(19) United States
(12) Patent Application Publication
(10) Pub. No.: US 2005/0122134 A1
(43) Pub. Date: Jun. 9, 2005

(54) Level shifter and flat panel display

(76) Inventors: Yong-Sung Park, Suwon-si (KR); Yang-Wan Kim, Suwon-si (KR)

Correspondence Address: CHRISTIE, PARKER & HALE, LLP, PO BOX 7068, PASADENA, CA, 91109-7068, US

(21) Appl. No.: 10/997,029

(22) Filed: Nov. 22, 2004

(30) Foreign Application Priority Data
Nov. 27, 2003 (KR) 10-2003-0085082

(51) Int. Cl. H03K 19/0175

(52) U.S. Cl. 326/81

(57) ABSTRACT

A level shifter includes first, second, third, and fourth transistors. The first transistor is operable by an applied first input signal and is for supplying a second input signal to a first main electrode of a transistor. The second transistor is operable by an applied second input signal and is for supplying a first input signal to a first main electrode of a transistor. The third transistor has a first main electrode coupled to a second main electrode of the first transistor and is operable by a signal outputted by the second transistor. The fourth transistor has a first main electrode coupled to a second main electrode of the second transistor and is operable by a signal outputted by the first transistor.

### CROSS REFERENCE TO RELATED APPLICATION

This application claims priority to and the benefit of Korea Patent Application No. 10-2003-0085082 filed on Nov. 27, 2003 in the Korean Intellectual Property Office, the entire content of which is incorporated herein by reference.

### BACKGROUND OF THE INVENTION

(a) Field of the Invention

The present invention relates to a level shifter and a flat panel display.

(b) Description of the Related Art

A voltage level shifter is required in the design of a semiconductor integrated circuit (IC) so as to provide an interface between circuits which need different voltage levels. For example, an IC such as a DRAM operates within the range of a given voltage, but it may further require a signal voltage of greater than the range of a given voltage in order to interface with external circuits or provide signals to other circuits.

The level shifter used for the above-described case is a circuit which is provided between two systems with different magnitudes of signal voltages, and modifies the magnitudes of signal voltages to thus couple the two systems. In particular, the level shifter is used when modifying the magnitudes of the signal voltages from a range of a small voltage to that of a large voltage.

FIG. 1 shows a circuit diagram of a conventional level shifter.

As shown, the conventional level shifter comprises two PMOS transistors MP1 and MP2, two NMOS transistors MN1 and MN2, two output terminals OUTA and OUTB, and two input terminals INA and INB.

The voltage levels of signals outputted through the output terminals OUTA and OUTB differ according to variation of logic states of signals inputted through the input terminals INA and INB in the above-configured level shifter.

The conventional level shifter requires an additional ground line since sources (or drains) of the NMOS transistors MN1 and MN2 operable by the input signals INA and INB are grounded. Also, power consumption is increased when the NMOS transistors MN1 and MN2 are turned off since Off currents flow to the ground terminal through the NMOS transistors MN1 and MN2. It is therefore desirable to provide a level shifter that overcomes the above-described shortcomings of the prior art while retaining their advantages.

### SUMMARY OF THE INVENTION

It is an aspect of the present invention to minimize power consumption in a level shifter.

It is another aspect of the present invention to provide a flat panel display using a level shifter of the present invention.

In one exemplary embodiment according to the present invention, a level shifter is provided. The level shifter includes a first transistor, a second transistor, a third transistor, and a fourth transistor. The first transistor is operable by an applied first input signal and is for supplying a second input signal to a first main electrode of the first transistor. The second transistor is operable by an applied second input signal and is for supplying a first input signal to a first main electrode of the second transistor. The third transistor has a first main electrode coupled to a second main electrode of the first transistor and is operable by a signal outputted by the second transistor. The fourth transistor has a first main electrode coupled to a second main electrode of the second transistor and is operable by a signal output by the first transistor. A first output signal is outputted through a first node where the second main electrode of the second transistor and the first main electrode of the fourth transistor are coupled, and a second output signal is outputted through a second node where the second main electrode of the first transistor and the first main electrode of the third transistor are coupled.

When the second transistor is turned off, the first and second main electrodes of the second transistor may change with each other according to the first input signal, and the Off current of the second transistor may be outputted to the direction of the first node. When the first transistor is turned off, the first and second main electrodes of the first transistor may change with each other according to the second input signal, and the Off current of the first transistor may be outputted in the direction of the second node.

The first and second transistors may be NMOS transistors, and the third and fourth transistors may be PMOS transistors, or the first and second transistors may be CMOS transistors, and the third and fourth transistors may be PMOS transistors. The second main electrodes of the third and fourth transistors may be coupled to a power supply voltage.

The first and second transistors may be PMOS transistors, and the third and fourth transistors may be NMOS transistors, or the first and second transistors may be CMOS transistors, and the third and fourth transistors may be NMOS transistors. The second main electrodes of the third and fourth transistors may be grounded.

The second input signal may be an inverted signal of the first input signal. The first and second output signals may have an inverted relationship.

### BRIEF DESCRIPTION OF THE DRAWINGS

The accompanying drawings, together with the specification, illustrate exemplary embodiments of the present invention, and, together with the description, serve to explain the principles of the present invention:

FIG. 1 shows a circuit diagram of a conventional level shifter;

FIG. 2 shows a circuit diagram of a level shifter according to a first exemplary embodiment of the present invention;

FIG. 3 shows a circuit diagram of a level shifter according to a second exemplary embodiment of the present invention;

FIG. 4 shows a circuit diagram of a level shifter according to a third exemplary embodiment of the present invention;

FIG. 5 shows a circuit diagram of a level shifter according to a fourth exemplary embodiment of the present invention; and

FIG. 6 shows a configuration diagram of a flat panel display using a level shifter according to an exemplary embodiment of the present invention.

### DETAILED DESCRIPTION

In the following detailed description, only certain exemplary embodiments of the present invention are shown and described, simply by way of illustration. As those skilled in the art would realize, the described embodiments may be modified in various different ways, all without departing from the spirit or scope of the present invention. Accordingly, the drawings and description are to be regarded as illustrative in nature, and not restrictive.

FIG. 2 shows a circuit diagram of a level shifter according to a first exemplary embodiment of the present invention.

As shown, the level shifter includes two PMOS transistors MP21 and MP22, two NMOS transistors MN21 and MN22, two output terminals OUT2A and OUT2B, and two input terminals IN2A and IN2B.

In detail, a drain of the transistor MP21 is coupled to a gate of the transistor MP22 and a first main electrode (a drain or a source) of the transistor MN21, and a drain of the transistor MP22 is coupled to a gate of the transistor MP21 and a first main electrode (a drain or a source) of the transistor MN22. A power supply voltage VDD2 is supplied to a source of the transistor MP21 and a source of the transistor MP22.

In these coupled states of the first exemplary embodiment, a first input signal of the input terminal IN2A can be provided to the gate of the transistor MN21 and a second main electrode (a source or a drain) of the transistor MN22, and a second input signal of the input terminal IN2B, which is an inverted signal of the first input signal of the input terminal IN2A, can be provided to the gate of the transistor MN22 and a second main electrode (a source or a drain) of the transistor MN21. A first output signal of the output terminal OUT2A can be outputted through the drain of the transistor MP22, and a second output signal of the output terminal OUT2B can be outputted through the drain of the transistor MP21 coupled to the gate of the transistor MP22.

An operation of the level shifter of FIG. 2 according to the first exemplary embodiment of the present invention will now be described.

When an external first input signal of the input terminal IN2A is applied to the gate of the transistor MN21, and a second input signal of the input terminal IN2B, which is an inverted signal of the first input signal of the input terminal IN2A, is applied to the gate of the transistor MN22, output signals of the output terminals OUT2A and OUT2B (having undergone the level shift process) are outputted from the drains of the transistors MP22 and MP21, respectively.

In detail, since the second input signal of the input terminal IN2B is a low level “L” signal when the first input signal of the input terminal IN2A is a high level “H” signal (the first operation mode), the transistor MN21 is turned on and the transistor MN22 is turned off. Hence, a low level signal is applied to the gate of the transistor MP22; the transistor MP22 is turned on; the current corresponding to the power supply voltage VDD2 flows through the transistor MP22; and accordingly, a high level first output signal of the output terminal OUT2A is outputted, and a low level second output signal of the output terminal OUT2B is outputted through a node 200 at which the drain of the transistor MP21 and the first main electrode of the transistor MN21 are coupled.

Since the gate of the transistor MN21 and the second main electrode of the transistor MN22 are coupled to the input terminal IN2A, the first and second main electrodes of the transistor MN22 are changed with each other when the first input signal of the input terminal IN2A is a high level “H” signal and the second input signal of the input terminal IN2B is a low level “L” signal. That is, when the first main electrode of the transistor MN22 is the drain and the second main electrode thereof is the source, the first main electrode is changed to become a source and the second main electrode is changed to become a drain. Accordingly, when the transistor MN22 is turned off because of the low level second input signal of the input terminal IN2B, the Off current of the transistor MN22 flows in the direction to a second node 210 where the output terminal OUT2A is coupled. As a result, since the Off current is added to the first output signal of the output terminal OUT2A, and they are outputted, the power consumption caused by the Off current is reduced.

By contrast, since the second input signal of the input terminal IN2B is a high level “H” signal when the first input signal of the input terminal IN2A is a low level “L” signal the transistor MN21 is turned off and the transistor MN22 is turned on. Thus, since now a low level signal is applied to the gate of the transistor MP21 and the transistor MP21 is turned on, the current corresponding to the power supply voltage VDD2 flows through the transistor MP21; a high level second output signal of the output terminal OUT2B is outputted; and a low level first output signal of the output terminal OUT2A′ is outputted through the second node 210 at which the drain of the transistor MP22 and the first main electrode of the transistor MN22 are coupled.

Similar to the first operation mode, since the gate of the transistor MN22 and the second main electrode of the transistor MN21 are coupled to the input terminal IN2B, the first and second main electrodes of the transistor MN21 are changed with each other when the first input signal of the input terminal IN2A is a low level “L” signal and the second input signal of the input terminal IN2B is a high level “H” signal. Accordingly, when the transistor MN21 is turned off because of the low level first input signal of the input terminal IN2A, the Off current of the transistor MN21 flows in the direction to the node 200 where the output terminal OUT2B is coupled. As a result, since the Off current is added to the second output signal of the output terminal OUT2B, and they are outputted, the power consumption caused by the Off current is reduced.

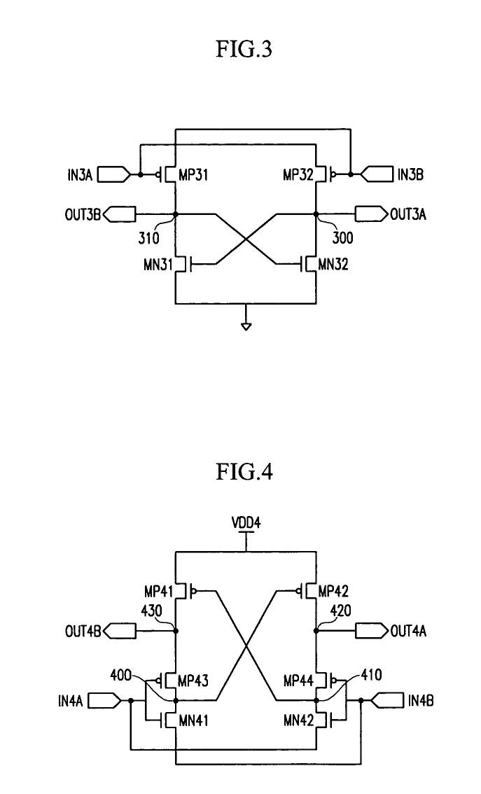

FIG. 3 shows a circuit diagram of a level shifter according to a second exemplary embodiment of the present invention.

As shown, the level shifter includes two PMOS transistors MP31 and MP32, two NMOS transistors MN31 and MN32, two output terminals OUT3A and OUT3B, and two input terminals IN3A and IN3B.

In operation, a first input signal of the input terminal IN3A is provided to a gate of the transistor MP31 and a first main electrode (a drain or a source) of the transistor MP32, and a second input signal of the input terminal IN3B is provided to a gate of the transistor MP32 and a first main electrode (a drain or a source) of the transistor MP31. A source of the transistor MN31 is coupled to the gate of the transistor MN32 and a second main electrode (a source or a drain) of the transistor MP31, and a source of the transistor MN32 is coupled to the gate of the transistor MN31 and a second main electrode (a source or a drain) of the transistor MP32. In these coupled states of the second exemplary embodiment, a first output signal of the output terminal OUT3A is outputted through the second main electrode of the transistor MP32 coupled to the gate of the transistor MN31, and a second output signal of the output terminal OUT3B is outputted through the second main electrode of the transistor MP31 coupled to the gate of the transistor MN32.

When the first input signal of the input terminal IN3A is a low level signal, the first and second main electrodes of the transistor MP32 are changed, and hence, when the transistor MP32 is turned off according to the high level second input signal of the input terminal IN3B, the Off current of the transistor MP32 flows in the direction to a node 300 where the output terminal OUT3A is coupled and is added to the first output signal of the output terminal OUT3A. Therefore, the power consumption caused by the Off current is reduced.

By contrast, when the second input signal of the input terminal IN3B is a low level signal, the first and second main electrodes of the transistor MP31 are changed, and hence, when the transistor MP31 is turned off according to the high level first input signal of the input terminal IN3A, the Off current of the transistor MP31 flows in the direction to a second node 310 where the output terminal OUT3B is coupled and is added to the second output signal of the output terminal OUT3B. Therefore, the power consumption caused by the Off current is reduced.

FIG. 4 shows a circuit diagram of a level shifter according to a third exemplary embodiment of the present invention.

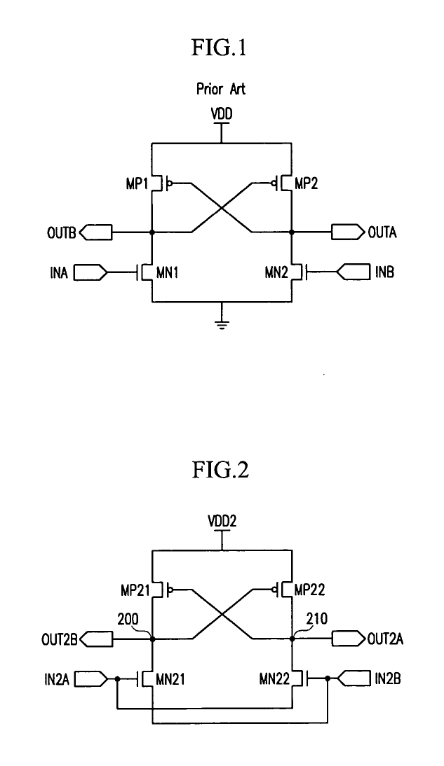

The configuration of the level shifter according to the third exemplary embodiment substantially corresponds to the level shifter of FIG. 1 according to the first exemplary embodiment except, for example, that first and second input signals of the input terminals IN4A and IN4B are provided to CMOS (complementary metal oxide semiconductor) transistors. Hence, the level shifter of FIG. 4 according to the third exemplary embodiment includes four PMOS transistors MP41, MP42, MP43, and MP44 and two NMOS transistors MN41 and MN42. The transistors MN41 and MP43 are referred to as first CMOS transistors, and the transistors MN42 and MP44 are referred to as second CMOS transistors.

In detail, drains of the transistors MP41 and MP42 are respectively coupled to first main electrodes (drains or sources) of the transistors MP43 and MP44 and Second main electrodes (drains or sources) of the transistors MP43 and MP44 are respectively coupled to first main electrodes (drains or sources) of the transistors MN41 and MN42. A gate of the transistor MP42 is coupled to a node 400 where the second main electrode of the transistor MP43 and the first electrode of the transistor MN41 are coupled. A gate of the transistor MP41 is coupled to a second node 410 where the second main electrode of the transistor MP44 and the first electrode of the transistor MN42 are coupled. Also, the input terminal IN4A is coupled to the gates of the transistors MP43 and MN41 and a second main electrode of the transistor MN42, and the input terminal IN4B is coupled to the gates of the transistors MP44 and MN42 and a second main electrode of the transistor MN41.

In these coupled states of the third exemplary embodiment, when the first input signal of the input terminal IN4A is high level, the transistor MN41 is turned on, the transistor MP43 is turned off, and a low level signal is applied to the gate of the transistor MP42, and hence, the transistor MP42 is turned on and a high-level first output signal of the output terminal OUT4A is outputted. The transistor MN42 is turned off and the transistor MP44 is turned on according to the low-level second input signal of the input terminal IN4B, and accordingly, a high level signal is applied to the gate of the transistor MP41 and a low-level second output signal of the output terminal OUT4B is outputted at the drain of the transistor MP41. Since the high-level first input signal of the input terminal IN4A is coupled to the second main electrode of the transistor MN42, the first and second main electrodes of the transistor MN42 are changed with each other, and the Off current of the transistor MN42 flows in the direction to where the output terminal OUT4A is coupled 420 and is added to the first output signal of the output terminal OUT4A.

When the first input signal of the input terminal IN4A is low level, the transistor MP41 is turned on, the transistor MP42 is turned off, and a high-level second output signal OUT4B and a low-level first output signal OUT4A are outputted. Since the high-level second input signal of the input terminal IN4B is coupled to the second main electrode of the transistor MN41, the first and second main electrodes of the transistor MN41 are changed with each other, and the Off current of the transistor MN41 flows in the direction to where the output terminal OUT4B is coupled 430 and is added to the second output signal of the output terminal OUT4B.

FIG. 5 shows a circuit diagram of a level shifter according to a fourth exemplary embodiment of the present invention.

The configuration of the level shifter according to the fourth exemplary embodiment substantially corresponds to that of the level shifter of FIG. 2 according to the second exemplary embodiment, and first and second input signals of respective input terminals IN5A and IN5B are inputted to CMOS transistors in substantially the same manner at the first and second input signals of respective input terminals IN4A and IN4B of FIG. 4 of the third exemplary embodiment. Hence, the level shifter according to the fourth exemplary embodiment comprises four NMOS transistors MN51, MN52, MN53, and MN54 and two PMOS transistors MP51 and MP52.

In detail, first main electrodes (drains or sources) of the transistors MN53 and MN54 are coupled to sources of the transistors MN51 and MN52 with drains coupled to the ground voltage, and coupling nodes 500, 510 of the transistors MN53 and MP51 and the transistors MN54 and MP52 forming the CMOS transistors are respectively coupled to gates of the transistors MN52 and MN51.

In these coupled states of the fourth exemplary embodiment, when the first input signal of the input terminal IN5A is high level, the transistor MN53 is turned on, the transistor MP51 is turned off, a low level signal is applied to the gate of the transistor MN52, and hence, the transistor MN52 is turned off and the high-level first output signal of the output terminal OUT5A is outputted. The transistor MN54 is turned off and the transistor MP52 is turned on according to the low-level second input signal of the input terminal IN5B, and accordingly, a high level signal is applied to the gate of the transistor MN51, and a low-level second output signal of the output terminal OUT5B is outputted at the drain of the transistor MN53. Since the high-level first output signal of the output terminal OUT5A is coupled to the second main electrode of the transistor MP52, the Off current of the transistor MN54 flows in the direction to where the output terminal OUT5A is coupled 520 and is added to the first output signal of the output terminal OUT5A.

When the first input signal of the input terminal IN5A is low level, the transistor MN52 is turned on, the transistor MN51 is turned off, and a low-level first output signal of the output terminal OUT5A and a high-level second output signal of the output terminal OUT5B are outputted. Since the high-level second input signal of input terminal IN5B is coupled to the second main electrode of the transistor MP51, the first and second main electrodes of the transistor MN53 are changed with each other, and the Off current of the transistor MN53 flows in the direction to where the output terminal OUT5B is coupled 530 and is added to the second output signal of output terminal OUT5B.

In the above described level shifters, it should be apparent to those skilled in the art that the voltage levels between ICs can be modified by applying the level shifters to the flat panel display using ICs with different voltage levels.

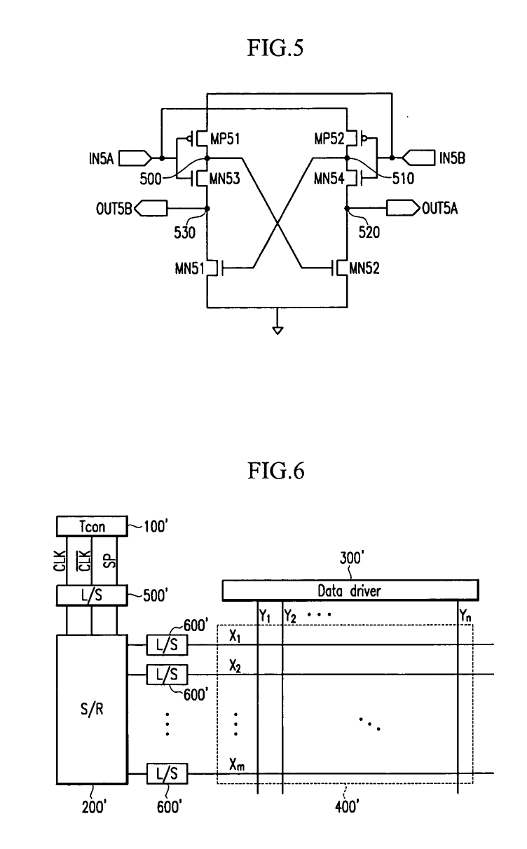

FIG. 6 shows a configuration diagram of a flat panel display using a level shifter according to an exemplary embodiment of the present invention.

The flat panel display comprises a timing controller Tcon 100′, a shift register S/R 200′, a data driver 300′, and a display panel 400′. The timing controller 100′ generates timing signals CLK, /CLK, and SP for driving the shift register 200′ and the data driver 300′. The shift register 200′ receives timing signals from the timing controller 100′ to sequentially apply scan signals to scan lines X1 through Xm formed on the display panel 400′. The data driver 300′ applies data signals to data lines Y1 through Yn of the display panel 400′ according to the timing signals.

For example, assuming that the voltage ranges used by the timing controller 100′ and the shift register 200′ are different, a level shifter L/S 500′ according to an embodiment is coupled between the timing controller 100′ and the shift register 200′ so that the output voltage range of the timing controller 100′ may be modified to a voltage range used by the shift register 200′.

In the like manner, assuming that the voltage ranges used by the shift register 200′ and the display panel 400′ are different, a level shifter L/S or level shifter L/Ss 600′ is (or are) formed between the shift register 200′ and the scan lines X1 through Xm of the display panel 400′ so that the output voltage range of the shift register 200′ may be modified to a voltage range used by the display panel 400′. A buffer (not illustrated) which follows the voltage range used by the display panel 400′ may also be formed between the level shifter 500′ and the display panel 400′.

FIG. 6 shows a case for respectively using a level shifter or shifters between the timing controller 100′ and the shift register 200′ and between the shift register 200′ and the display panel 400′ for exemplary purposes only, and the invention is not restricted to this case, and the invention and the above description may be applied to other cases for modifying voltage ranges of the flat panel display.

In addition, it should be apparent to those skilled in the art that, in certain embodiments of the present invention, the power consumption caused by the Off current is minimized since the Off current of the transistor in the level shifter is included in the output signal. Also, simpler signal lines are formed since no additional ground line for the transistor operable by the input signal is required.

While this invention has been described in connection with certain exemplary embodiments, it is to be understood that the invention is not limited to the disclosed embodiments, but, on the contrary, is intended to cover various modifications and equivalents included within the spirit and scope of the appended claims, and equivalent thereof.

1. A level shifter comprising:
a first transistor, operable by an applied first input signal, for supplying a second input signal to a first main electrode of the first transistor;
a second transistor, operable by an applied second input signal, for supplying a first input signal to a first main electrode of the second transistor;
a third transistor having a first main electrode of the third transistor coupled to a second main electrode of the first transistor via a second node, and being operable by a signal outputted by the second transistor; and
a fourth transistor having a first main electrode of the fourth transistor coupled to a second main electrode of the second transistor via a first node, and being operable by a signal outputted by the first transistor, and wherein
a first output signal is outputted through the first node where the second main electrode of the second transistor and the first main electrode of the fourth transistor are coupled, and
a second output signal is outputted through the second node where the second main electrode of the first transistor and the first main electrode of the third transistor are coupled.

2. The level shifter of claim 1, wherein the first transistor comprises a gate of the first transistor and wherein the first transistor is operable by the applied first input signal via the gate of the first transistor.

3. The level shifter of claim 2, wherein the gate of the first transistor is coupled to the first main electrode of the second transistor.

4. The level shifter of claim 2, wherein the first input signal is applied with the applied first input signal to the first transistor.

5. The level shifter of claim 1, wherein the second transistor is further operable by the second input signal.

6. The level shifter of claim 5, wherein the second transistor comprises a gate of the second transistor, wherein the gate of the second transistor is coupled to the first main electrode of the first transistor, and wherein the second transistor is operable by the second input signal via the gate of the second transistor.

7. The level shifter of claim 5, wherein the second input signal is applied with the applied second input signal to the second transistor at a third node.

8. The level shifter of claim 1, wherein when the second transistor is turned off, the first and second main electrodes of the second transistor are changed with each other according to the first input signal, and the Off current of the second transistor is outputted in the direction of the first node.

9. The level shifter of claim 1, wherein when the first transistor is turned off, the first and second main electrodes of the first transistor are changed with each other according to the second input signal, and the Off current of the first transistor is outputted in the direction of the second node.

10. The level shifter of claim 1, wherein the first and second transistors are NMOS transistors, and the third and fourth transistors are PMOS transistors.

11. The level shifter of claim 10, wherein the third and fourth transistors each comprises a second main electrode and wherein the second main electrodes of the third and fourth transistors are coupled to a power supply voltage.

12. The level shifter of claim 1, wherein the first and second transistors are CMOS transistors, and the third and fourth transistors are PMOS transistors.

13. The level shifter of claim 1, wherein the first and second transistors are PMOS transistors, and the third and fourth transistors are NMOS transistors.

14. The level shifter of claim 13, wherein the third and fourth transistors each comprises a second main electrode and wherein the second main electrodes of the third and fourth transistors are grounded.

15. The level shifter of claim 1, wherein the first and second transistors are CMOS transistors, and the third and fourth transistors are NMOS transistors.

16. The level shifter of claim 1, wherein the second input signal is an inverted signal of the first input signal.

17. The level shifter of claim 1, wherein the first and second output signals have an inverted relationship.

18. The level shifter of claim 1, wherein the level shifter is formed within a flat panel display.

19. A level shifter comprising:
a first transistor, operable by an applied first input signal, for outputting a first output signal, the first transistor including a first main electrode of the first transistor;
a second transistor, operable by an applied second input signal, for outputting a second output signal, the second transistor including a first main electrode of the second transistor;
a third transistor, operable by the second output signal, for varying states of the first output signal; and
a fourth transistor, operable by the first output signal, for varying states of the second output signal, and wherein
a second input signal is applied to the first main electrode of the first transistor, and a first input signal is applied to the first main electrode of the second transistor.

20. The level shifter of claim 19, wherein the second input signal is an inverted signal of the first input signal.

21. The level shifter of claim 19, wherein the level shifter is formed within a flat panel display.
